(19) United States
(12) Patent Application Publication
(10) Pub. No.: US 2025/0280708 A1
(43) Pub. Date: Sep. 4, 2025

(54) DISPLAY DEVICE

(71) Applicant: LG Display Co., Ltd., Seoul (KR)

(72) Inventors: SangUk AHN, Paju-si (KR); HeeYoung KWACK, Paju-si (KR); TaeHo KIM, Paju-si (KR)

(21) Appl. No.: 18/972,230

(22) Filed: Dec. 6, 2024

(30) Foreign Application Priority Data
Feb. 29, 2024 (KR) 10-2024-0030099

(51) Int. Cl. H10K 59/80; H10K 59/123; H10K 59/32

(52) U.S. Cl. CPC H10K 59/873; H10K 59/123; H10K 59/32; H10K 59/80521

(57) ABSTRACT

Embodiments of the disclosure relate to a display device capable of preventing or reducing side moisture permeation due to delamination. The display device includes a substrate including a display area, a through-hole, and a non-display area between the display area and the through-hole, a light emitting element disposed in the display area, a pattern area disposed in the non-display area and including at least one metal pattern, and an encapsulation layer positioned on the light emitting element and including an inorganic film. The inorganic film is disposed in the pattern area, and a side portion of a metal pattern adjacent to the through-hole among the at least one metal pattern is exposed through the through-hole.

### CROSS-REFERENCE TO RELATED APPLICATION

This application claims priority from Korean Patent Application No. 10-2024-0030099, filed on Feb. 29, 2024, which is hereby incorporated by reference for all purposes as if fully set forth herein.

### BACKGROUND

### Technical Field

Embodiments of the disclosure relate to display devices.

### Description of the Related Art

As technology advances, the uses of display devices are becoming more diverse. Further, as display devices become thinner and lighter, their range of use is expanding.

As the area occupied by the display area for displaying images in the display device increases, various functions associated with or linked to the display device are added.

As design for allowing the display area to look full, so-called bezel-less or bezel-free design, becomes commonplace, research efforts are required for display devices having an area for adding various features as well as image display, inside the display area.

Accordingly, proposed are hole-in displays (HIDs) or hole-in active area (HiAA) displays in which at least a portion of the substrate has been removed in the display area of the display panel.

### BRIEF SUMMARY

Moisture permeation may occur in the substrate-removed area in the display area, deteriorating display quality. The inventors of the disclosure thus have invented a display device capable of preventing or reducing side moisture permeation due to delamination.

Embodiments of the disclosure may provide a display device with enhanced coupling force as a fixing stress acts between an inorganic film and an upper metal layer of a metal pattern.

Embodiments of the disclosure may provide a display device capable of blocking moisture permeation path due to an organic light emission stack by disposing a side portion of some metal layer of a metal pattern to be exposed through a through hole.

Embodiments of the disclosure may provide a display device capable of preventing or reducing side moisture permeation due to delamination by blocking the moisture permeation path due to an inorganic light emission stack while enhancing the coupling force between the metal pattern and the inorganic film.

Embodiments of the disclosure may provide a display device capable of process optimization by freeing a limit to the number of metal patterns due to a cut margin of a through hole as metal patterns are consecutively disposed.

Embodiments of the disclosure may provide a display device comprising a substrate including a display area, a through-hole, and a non-display area between the display area and the through-hole, a light emitting element disposed in the display area, a pattern area disposed in the non-display area and including at least one metal pattern, and an encapsulation layer positioned on the light emitting element and including an inorganic film.

Embodiments of the disclosure may provide a display device in which the inorganic film is disposed in the pattern area, and a side portion of a metal pattern adjacent to the through-hole among the at least one metal pattern is exposed through the through-hole.

Embodiments of the disclosure may provide a display device comprising a substrate, a through-hole formed by removing at least a portion of the substrate, a display area positioned around the through-hole, wherein a subpixel including a light emitting element and a transistor for driving the light emitting element is disposed in the display area, a pattern area positioned between the display area and the through-hole and including a metal pattern having a side portion exposed through the through-hole, and an inorganic film disposed on the light emitting element and the pattern area.

According to embodiments of the disclosure, there may be provided a display device for preventing or reducing side moisture permeation due to delamination.

According to embodiments of the disclosure, there may be provided a display device with enhanced coupling force as a fixing stress acts between an inorganic film and an upper metal layer of a metal pattern.

According to embodiments of the disclosure, there may be provided a display device capable of blocking moisture permeation path due to an organic light emission stack by disposing a side portion of some metal layer of a metal pattern to be exposed through a through hole.

According to embodiments of the disclosure, there may be provided a display device capable of preventing or reducing side moisture permeation due to delamination by blocking the moisture permeation path due to an inorganic light emission stack while enhancing the coupling force between the metal pattern and the inorganic film.

According to embodiments of the disclosure, there may be provided a display device capable of low power consumption by enhancing the lifespan by preventing or reducing side moisture permeation due to delamination.

According to embodiments of the disclosure, there may be provided a display device capable of process optimization by freeing a limit to the number of metal patterns due to a cut margin of a through hole as metal patterns are consecutively disposed.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 illustrates an equivalent circuit diagram illustrating a subpixel in a display panel according to embodiments of the disclosure;

FIG. 3 is a plan view illustrating a structure of an optical area of a display panel according to embodiments of the disclosure;

FIG. 4 is a cross-sectional view taken along line I-I′ of FIG. 3;

FIG. 5 is a cross-sectional view taken along line II-II′ of FIG. 3.

FIG. 6 is an example cross-sectional enlarged view illustrating area X of FIG. 5;

FIG. 7 is another example cross-sectional enlarged view illustrating area X of FIG. 5;

FIG. 8 is another example cross-sectional enlarged view illustrating area X of FIG. 5;

FIG. 9 is an example cross-sectional enlarged view illustrating area Y of FIG. 6;

FIG. 10 is a view illustrating a moisture permeation path in a hole area boundary of a display panel;

FIG. 11 is a view illustrating delamination caused by moisture permeation; and

FIGS. 12 and 13 are views illustrating a process for forming an optical area of a display panel according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

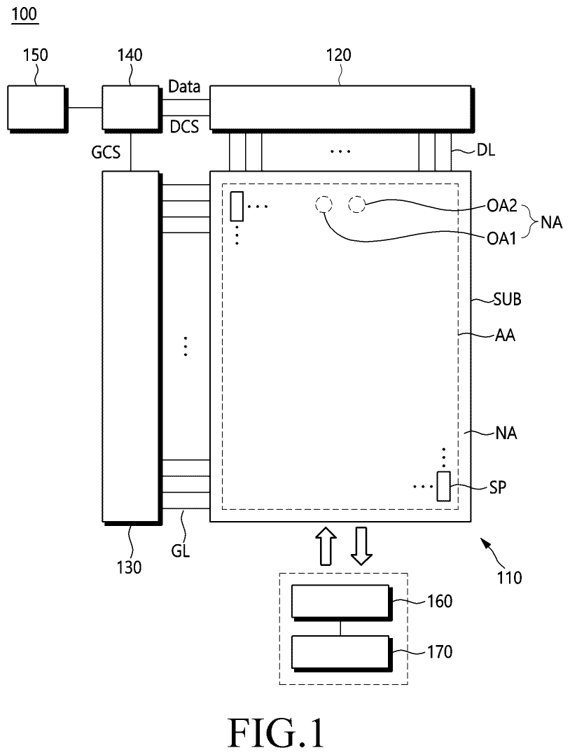

FIG. 1 is a view illustrating a system configuration of a display device 100 according to embodiments of the disclosure.

Referring to FIG. 1, the display device 100 may include a display panel 110 and a display driving circuit as components for displaying an image.

The display driving circuits are circuits for driving the display panel 110 and may include a data driving circuit 120, a gate driving circuit 130, and a display controller 140.

The display panel 110 may include a display area AA in which images are displayed and a non-display area NA in which no image is displayed. The non-display area NA may be an outer area of the display area AA and be referred to as a bezel area. The whole or part of the non-display area NA may be an area visible from the front surface of the display device 100 or an area that is bent and not visible from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a light emitting display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction.

Here, the first direction may be a column direction and the second direction may be a row direction. The first direction may be the row direction, and the second direction may be the column direction.

The data driving circuit 120 is a circuit configured to drive the plurality of data lines DL, and may output data signals to the plurality of data lines DL. The gate driving circuit 130 is a circuit configured to drive the plurality of gate lines GL, and may output gate signals to the plurality of gate lines GL.

The display controller 140 may be a device configured to control the operation of the data driving circuit 120 and the gate driving circuit 130. The display controller 140 may control driving timings for the plurality of data lines DL and driving timings for the plurality of gate lines GL.

The display controller 140 may supply the data driving control signal DCS to the data driving circuit 120 to control the data driving circuit 120. The display controller 140 may supply the gate driving circuit control signal GCS to the gate driving circuit 130 to control the gate driving circuit 130.

The display controller 140 may receive input image data from the host system 150 and supply image data Data to the data driving circuit 120 based on the input image data.

The data driving circuit 120 may supply data signals to the plurality of data lines DL according to the driving timing control of the display controller 140.

The data driving circuit 120 may receive digital image data Data from the display controller 140 and may convert the received image data Data into analog data signals and output them to the plurality of data lines DL.

The gate driving circuit 130 may supply gate signals to the plurality of gate lines GL according to the timing control of the display controller 140. The gate driving circuit 130 may receive a first gate voltage corresponding to a turn-on level voltage and a second gate voltage corresponding to a turn-off level voltage, along with various gate driving circuit control signals GCS, generate gate signals, and supply the generated gate signals to the plurality of gate lines GL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected with the display panel 110 by a tape automated bonding (TAB) method or connected to a bonding pad of the self-emission display panel 110 by a COG or chip on panel (COP) method or may be connected with the display panel 110 according to a COF method. The gate driving circuit 130 may be formed in a gate in panel (GIP) type, in the non-display area NA of the display panel 110. The gate driving circuit 130 may be disposed on the substrate SUB or may be connected to the substrate SUB. In other words, the gate driving circuit 130 that is of a gate in panel (GIP) type may be disposed in the non-display area NA of the substrate SUB. The gate driving circuit 130 that is of a chip-on-glass (COG) type or chip-on-film (COF) type may be connected to the substrate.

Meanwhile, at least one of the data driving circuit 120 and the gate driving circuit 130 may be disposed in the display area AA of the display panel 110. For example, at least one of the data driving circuit 120 and the gate driving circuit 130 may be disposed not to overlap the subpixels SP or to overlap all or some of the subpixels SP.

The data driving circuit 120 may be connected with one side (e.g., an upper or lower side) of the display panel 110. Depending on the driving scheme or the panel design scheme, the data driving circuit 120 may be connected with both sides (e.g., upper and lower sides) of the self-emission display panel 110, or two or more of the four sides of the self-emission display panel 110.

The gate driving circuit 130 may be connected with one side (e.g., a left or right side) of the display panel 110. Depending on the driving scheme or the panel design scheme, the gate driving circuit 130 may be connected with both sides (e.g., left and right sides) of the display panel 110, or two or more of the four sides of the display panel 110.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be electrically connected to the data driving circuit 120 and the gate driving circuit 130 through a printed circuit board (PCB) or a flexible printed circuit board (FPCB).

The display controller 140 may transmit/receive signals to/from the data driving circuit 120 according to one or more predetermined interfaces. The interface may include, e.g., a low voltage differential signaling (LVDS) interface, an EPI interface, and a serial peripheral interface (SPI).

Referring to FIG. 1, the display device 100 according to embodiments of the disclosure may include one or more optical areas (OA) where at least a portion of the substrate SUB has been removed.

One or more components (not shown) for providing various functions may be disposed in an area at least partially overlapping the optical area OA. The one or more components may be, e.g., an optical electronic device, a clock hand, etc.

The optical electronic device may include one or more of a capture device, such as a camera (image sensor), and a detection sensor, such as a proximity sensor and an illuminance sensor.

For example, a capture device, such as a camera, may be positioned under a first optical area OA1, and a detection sensor may be positioned under a second optical area OA2.

The component may be positioned under the substrate SUB. The component may be positioned to at least partially overlap the optical area OA.

The first optical area OA1 and the second optical area OA2 may have various shapes, such as a circle, an ellipse, a square, a hexagon, or an octagon. The shapes of the first optical area OA1 and the second optical area OA2 may be the same or different. The area of the first optical area OA1 may be the same as or different from the area of the second optical area OA2.

For convenience of description, an example in which the first optical area OA1 and the second optical area OA2 are circular and are identical in area is described below, but the disclosure is not limited thereto.

At least one optical area OA is positioned in the area where the substrate SUB has been removed, and the optical area OA may be a non-display area NA where no subpixel SP is disposed.

The optical area OA positioned in the display area AA is also referred to as a “hone in display (HID)” or “hole in active area (HiAA)” area.

Signal lines (e.g., data lines DL or gate lines GL) disposed on the substrate SUB may be disposed around (or bypassing) the periphery of the optical area OA.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 160 that drives and senses the touch sensor and generates and outputs touch sensing data and a touch controller 170 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 160.

The touch sensor in the form of a touch panel may exist outside the display panel 110, or the touch sensor may exist inside the display panel 110.

When the touch panel, in the form of a panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit 160 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen).

According to the self-capacitance sensing scheme, each of the plurality of touch electrodes may serve both as a driving touch electrode and as a sensing touch electrode. The touch driving circuit 160 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes.

According to the mutual-capacitance sensing scheme, the plurality of touch electrodes are divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit may be implemented as separate devices or as a single device. The touch driving circuit 160 and the data driving circuit 120 may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display device in various types and various sizes capable of displaying information or images.

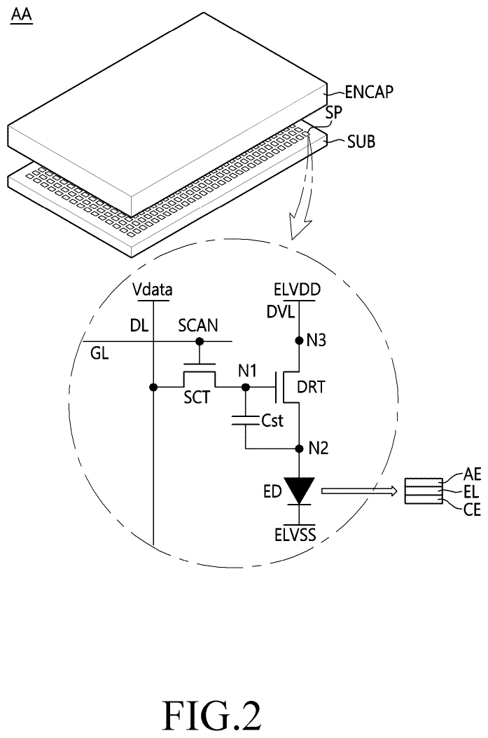

FIG. 2 is an equivalent circuit of a subpixel SP in a display panel 110 according to embodiments of the disclosure. What is identical or similar to those described with reference to FIG. 1 is omitted from the following description or briefly described below.

Referring to FIG. 2, each subpixel SP in the display area AA of the display panel 110 may include a light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT may include the first node N1 to which the data voltage Vdata may be applied, a second node N2 electrically connected with the light emitting element ED, and a third node N3 to which a high-potential common voltage ELVDD is applied from a driving voltage line DVL. The first node N1 in the driving transistor DRT may be a gate node, the second node N2 may be either a source node or a drain node, and the third node N3 may be the other of the source node and the drain node.

The light emitting element ED1 may include an anode electrode AE which is a first electrode, a light emitting layer EL, and a cathode electrode CE which is a second electrode. The anode electrode AE may be a pixel electrode disposed in each subpixel SP and be electrically connected to the second node N2 of the driving transistor DRT of each subpixel SP. The cathode electrode CE may be a common electrode commonly disposed in the plurality of subpixels SP, and a low-potential common voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

For example, the light emitting element ED may be an organic light emitting diode (OLED), an inorganic light emitting diode, or a quantum dot light emitting element. In this case, when the light emitting element ED is an organic light emitting diode, the light emitting layer EL of the light emitting element ED may include an organic light emitting layer including an organic material.

The on/off of the scan transistor SCT is controlled by the scan signal SCAN, which is a gate signal applied through the gate line GL. The scan transistor SCT may switch the electrical connection between the data line DL and the first node N1 of the driving transistor DRT.

The storage capacitor Cst may be electrically connected between the first node N1 and second node N2 of the driving transistor DRT.

Each subpixel SP may have a 2T (transistor) 1C (capacitor) structure which includes two transistors DRT and SCT and one capacitor Cst as shown in FIG. 2 and, in some cases, each subpixel SP may further include one or more transistors or one or more capacitors.

The capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DRT.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

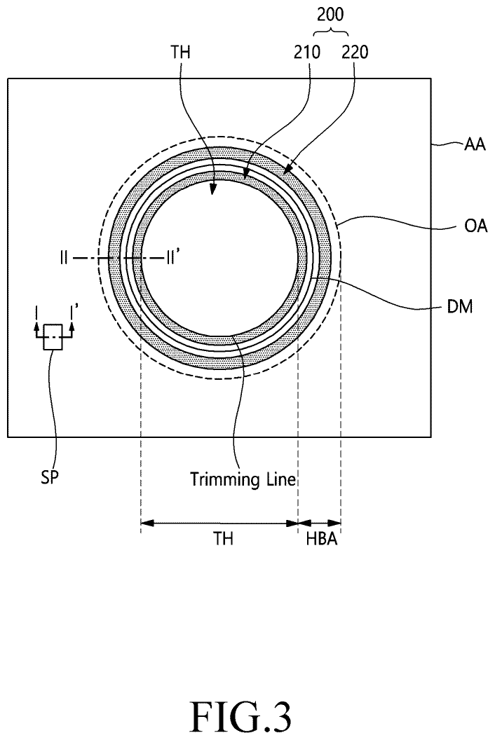

FIG. 3 is a plan view illustrating a structure of an optical area OA of a display panel 110 according to embodiments of the disclosure. What is identical or similar to those described in connection with FIGS. 1 and 2 may be omitted or briefly described below.

Referring to FIG. 3, the optical area OA is disposed in the display area AA. Subpixels SP may be disposed around the optical area OA. The optical area OA may be either the first optical area OA1 or the second optical area OA2 described above.

Referring to FIG. 3, the optical area OA may include a through hole TH and a bezel area around the through hole TH. The bezel area positioned between the through hole TH and the display area AA is also referred to as a “HiAA bezel area HBA”.

A pattern area 200 may be positioned in the HiAA bezel area HBA to prevent fine cracks and moisture permeation introduced from the outside through the trimming line. A metal pattern may be disposed in the pattern area 200. A subpixel for displaying an image may not be positioned in the optical area OA. In other words, the optical area OA including the “HiAA bezel area” may be a non-display area NA in which an image is not displayed.

The through-hole TH may be formed by removing the substrate along a trimming line. The shape of the through-hole TH may be circular from a plan view as shown in FIG. 3, but may have various shapes, such as an oval, a square, a hexagon, or an octagon from a plan view.

The pattern area 200 may include an outer pattern area 210 and an inner pattern area 220.

Referring to FIG. 3, in the HiAA bezel area HBA, a dam DM that separates two pattern areas 210 and 220 may be positioned between the outer pattern area 210 and the inner pattern area 220. The outer pattern area 210 may be positioned between the dam DM and the through-hole TH, and the inner pattern area 220 may be positioned between the display area AA and the dam DM.

A dam (not shown) may be further positioned in the inner pattern area 220 positioned between the dam DM and the display area AA. A dam (not shown) may be further positioned in the outer pattern area 210 positioned between the dam DM and the through-hole TH. The dam may be disposed to prevent the encapsulation layer from overflowing the display area AA.

The shape of the dam DM has a closed curve shape surrounding the through-hole TH while corresponding to the shape of the through-hole TH. The dam DM and the through-hole TH may have different closed curve shapes, but may have the same shape but different closed curve shapes. For example, the dam DM and the through-hole TH may have concentric shapes and may be disposed to be spaced apart from each other by a predetermined interval.

As shown in FIG. 3, a dam DM is between the through-hole TH and the display area AA. Here, the dam DM surrounds the through-hole TH from a plan view. Further, the dam DM is adjacent to the metal patterns 211, 212, 213, 214, 215, 216, 221, 222, 223, and 224.

From a plan view, the pattern area 200 has a closed curve shape surrounding the through-hole TH while corresponding to the shape of the through-hole TH. The pattern area 200 may have a closed curve shape different from that of the through-hole TH, but may have a closed curve shape having the same shape but different sizes. For example, as illustrated in FIG. 3, the pattern area 200 and the through-hole TH may have the same shape and may be disposed to be spaced apart from each other by a predetermined interval.

Meanwhile, the subpixel SP disposed in the display area AA may include a light emitting element. A light emitting stack (not shown) including a light emitting layer may be positioned in the display area AA. When the light emitting element is an organic light emitting element, the light emitting stack may be an organic light emitting stack including an organic material.

The organic light emitting stack may be disposed up to at least a partial area of the optical area OA.

Meanwhile, when moisture permeates into the organic light emitting stack, defects such as dead subpixels may occur. There is a possibility that moisture may permeate in the area where the through-hole TH is positioned.

An inorganic encapsulation layer may be positioned on the pattern area 200. Moisture may permeate through the inorganic encapsulation layer, and the pattern area 200 may lengthen the path through which moisture permeates from the inorganic encapsulation layer. Accordingly, the pattern area 200 may prevent moisture introduced from the through-hole TH or the like from reaching the light emitting layer positioned in the display area AA.

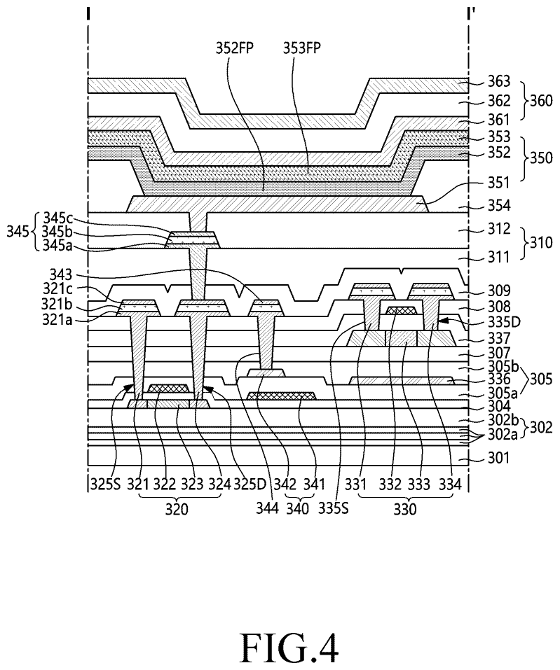

FIG. 4 is a cross-sectional view taken along line I-I′ of FIG. 3. For example, FIG. 4 is a cross-sectional view of the subpixel SP of FIG. 3. What is identical or similar to those described with reference to FIGS. 1 to 3 is omitted from the following description or briefly described below.

Referring to FIG. 4, a substrate 301 and a buffer layer 302 may be provided. The buffer layer 302 may include a multi-buffer layer 302a and a lower buffer layer 302b. A first transistor 320 may be disposed on the lower buffer layer 302b. A lower gate insulation film 304 may be disposed to insulate the first semiconductor layer 323 constituting the first transistor 320 from the first gate electrode 322 on the first semiconductor layer 323. A lower interlayer insulation film 305 may be disposed on the first gate electrode 322. In the lower interlayer insulation film 305, a first lower interlayer insulation film 305a and a second lower interlayer insulation film 305b may be sequentially disposed. An upper buffer layer 307 may be disposed on the lower interlayer insulation film 305.

The substrate 301 may include an insulating material. For example, the substrate 301 may include glass or plastic. The substrate 301 may have a single layer structure or a multilayer structure. For example, the substrate 301 may have a multilayer structure. The substrate 301 may include a first substrate and a second substrate, and may include an intermediate film between the first substrate and the second substrate. The first substrate and the second substrate may include the same material. For example, the first substrate and the second substrate may be polyimide (PI) substrates. The intermediate film may be a single layer or a multilayer inorganic layer of silicon nitride (SiNx) or silicon oxide (SiOx). By disposing an intermediate film between the first substrate and the second substrate, it is possible to prevent moisture components from penetrating through the lower first substrate into the transistor, thereby enhancing reliability of the display device.

The multi-buffer layer 302a may delay diffusion of moisture or oxygen penetrating into the substrate 301, and may be formed by alternately stacking silicon nitride (SiNx) and silicon oxide (SiOx) at least once.

The lower buffer layer 302b may protect the first semiconductor layer 323 and may block various types of defects introduced from the substrate. The lower buffer layer 302b may be formed of amorphous silicon (a-Si), silicon nitride (SiNx), silicon oxide (SiOx), or the like.

The first semiconductor layer 323 of the first transistor 320 may be formed of a polycrystalline semiconductor layer, and the first semiconductor layer 323 may include a channel area, a source area, and a drain area.

The polycrystalline semiconductor layer has higher mobility than the amorphous semiconductor layer and the oxide semiconductor layer, and thus has low energy consumption power and excellent reliability. As such, the polycrystalline semiconductor layer may be used for the driving transistor.

The first gate electrode 322 may be disposed on the lower gate insulation film 304 and may be disposed to overlap the first semiconductor layer 323.

The second transistor 330 may be disposed on the upper buffer layer 307, and the light blocking layer 336 may be disposed under an area corresponding to the second transistor 330.

Referring to FIG. 4, the light blocking layer 336 may be disposed on the first lower interlayer insulation film 305a of the area corresponding to the second transistor 330, and the second semiconductor layer 333 of the second transistor 330 may be disposed on the second lower interlayer insulation film 305b and the upper buffer layer 307 to overlap the light blocking layer 336. An upper gate insulation film 337 for insulating the second gate electrode 332 and the second semiconductor layer 333 may be disposed on the second semiconductor layer 333, and then an upper interlayer insulation film 308 may be disposed on the second gate electrode 332. The first gate electrode 322 and the second gate electrode 332 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

The first and second lower interlayer insulation films 305a and 305b may be formed of an inorganic layer having a higher hydrogen particle content than the upper interlayer insulation film 308. For example, the first and second lower interlayer insulation films 305a and 305b may be formed of silicon nitride (SiNx) formed by a deposition process using NH3 gas, and the upper interlayer insulation film 308 may be formed of silicon oxide (SiOx). The hydrogen particles included in the first and second lower interlayer insulation films 305a and 305b may be diffused to the polycrystalline semiconductor layer during the hydrogenation process to fill the voids in the polycrystalline semiconductor layer with hydrogen. Accordingly, the polycrystalline semiconductor layer may be stabilized, thereby preventing the characteristic degradation of the first transistor 320.

The second semiconductor layer 333 of the second transistor 330 may be formed after the first semiconductor layer 323 of the first transistor 320 is activated and hydrogenated, and the second semiconductor layer 333 may be formed of an oxide semiconductor. Since the second semiconductor layer 333 is not exposed to the high-temperature atmosphere of the activation and hydrogenation process of the first semiconductor layer 323, the second semiconductor layer 333 may be prevented from being damaged, thereby enhancing reliability.

After the upper interlayer insulation film 308 is disposed, the first source contact hole 325S and the first drain contact hole 325D may be formed to correspond to the source and drain areas, respectively, of the first transistor, and the second source contact hole 335S and the second drain contact hole 335D may be formed to correspond to the source and drain areas, respectively, of the second transistor 330.

Referring to FIG. 4, the first source contact hole 325S and the first drain contact hole 325D may be continuously formed from the upper interlayer insulation film 308 to the lower gate insulation film 304, and the second source contact hole 335S and the second drain contact hole 335D may also be formed in the second transistor 330. The first source electrode 321 and the first drain electrode 324 corresponding to the first transistor 320, and the second source electrode 331 and the second drain electrode 334 corresponding to the second transistor 330 may be concurrently (or in some embodiments, simultaneously) formed, thereby reducing the number of processes for forming the respective source and drain electrodes of the first transistor 320 and the second transistor 330.

The first source and drain electrodes 321 and 324 and the second source and drain electrodes 331 and 334 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

The first source and drain electrodes 321 and 324 and the second source and drain electrodes 331 and 334 may be formed in a triple layer structure. The first source electrode 321 may sequentially include a first electrode layer 321a, a second electrode layer 321b, and a third electrode layer 321c.

The first electrode layer 321a, the second electrode layer 321b, and the third electrode layer 321c may include materials having relatively different etching speeds. The second electrode layer 321b may include a material having a relatively fast etching speed, and the first electrode layer 321a and the third electrode layer 321c may include a material having a relatively slow etching speed. The etching speed of the second electrode layer 321b may be relatively faster than the etching speeds of the first electrode layer 321a and the third electrode layer 321c.

For example, the second electrode layer 321b may include aluminum (Al) having a relatively fast etching speed, and the first electrode layer 321a and the third electrode layer 321c may include titanium (Ti) having a relatively slow etching speed. The first source electrode 321 may have a triple layer structure of Ti/Al/Ti.

Other source and drain electrodes may have the same structure as the first source electrode 321.

A storage capacitor 340 may be disposed between the first transistor 320 and the second transistor 330. As illustrated in FIG. 4, the storage capacitor 340 may be formed by overlapping the storage lower electrode 341 and the storage upper electrode 342 with the first lower interlayer insulation film 305a interposed therebetween.

The storage lower electrode 341 may be positioned on the lower gate insulation film 304 and may be formed of the same material on the same layer as the first gate electrode 322. The storage upper electrode 342 may be electrically connected to the pixel circuit through the storage supply line 343. The storage upper electrode 342 may be formed of the same material on the same layer as the light blocking layer 336. The storage upper electrode 342 is exposed through the storage contact hole 344 passing through the second lower interlayer insulation film 305b, the upper buffer layer 307, the upper gate insulation film 337, and the upper interlayer insulation film 308 to be connected to the storage supply line 343. Meanwhile, the storage upper electrode 342 is spaced apart from the light blocking layer 336 as illustrated in FIG. 4, but may be integrally formed to be connected to each other. The storage supply line 343 may be formed of the same material on the same plane as the first source and drain electrodes 321 and 324 to the second source and drain electrodes 331 and 334, and thus the storage supply line 343 may be formed concurrently (or in some embodiments, simultaneously) with the first source and drain electrodes 321 and 324 to the second source and drain electrodes 331 and 334 through the same mask process.

A protective layer 309 may be formed by depositing an inorganic insulating material such as SiNx or SiOx on the substrate 301 on which the first source and drain electrodes 321 and 324, the second source and drain electrodes 331 and 334, and the storage supply line 343 are formed.

A planarization layer 310 may be formed on the substrate 301 on which the protective layer 309 is formed. The planarization layer 310 may include a first planarization layer 311 and a second planarization layer 312.

Specifically, the first planarization layer 311 may be disposed by fully applying an organic insulating material such as an acrylic resin on the substrate 301 on which the protective layer 309 is formed.

The protective layer 309 and the first planarization layer 311 may be disposed, and a contact hole exposing the first source electrode 321 or the first drain electrode 324 of the first transistor 320 may be formed through a photolithography process. The connecting electrode 345 may be disposed in a contact hole area exposing the first drain electrode 324.

The connecting electrode 345 may be a single layer or a multilayer formed of any one of molybdenum (Mo), aluminum (Al), chromium (Cr), gold (Au), titanium (Ti), nickel (Ni), neodymium (Nd), and copper (Cu), or an alloy thereof, but is not limited thereto.

The connecting electrode 345 may have a triple layer structure. The connecting electrode 345 may sequentially include a first connecting electrode layer 345a, a second connecting electrode layer 345b, and a third connecting electrode layer 345c.

The first connecting electrode layer 345a, the second connecting electrode layer 345b, and the third connecting electrode layer 345c may include materials having relatively different etching speeds. The second connecting electrode layer 345b may include a material having a relatively fast etching speed, and the first connecting electrode layer 345a and the third connecting electrode layer 345c may include a material having a relatively slow etching speed. The etching speed of the second connecting electrode layer 345b may be relatively faster than the etching speeds of the first connecting electrode layer 345a and the third connecting electrode layer 345c.

For example, the second connecting electrode layer 345b may include aluminum (Al) having a relatively fast etching speed, and the first connecting electrode layer 345a and the third connecting electrode layer 345c may include titanium (Ti) having a relatively slow etching speed. The connecting electrode 345 may have a triple layer structure of Ti/Al/Ti.

The second planarization layer 312 may be disposed on the connecting electrode 345, and the light emitting element 350 connected to the first transistor 320 may be disposed by forming a contact hole exposing the connecting electrode 345 in the second planarization layer 312.

The light emitting element 350 may include an anode electrode 351 connected to the first drain electrode 324 of the first transistor 320, at least one organic light emitting stack 352 formed on the anode electrode 351, and a cathode electrode 353 formed on the organic light emitting stack 352.

The organic light emitting stack 352 may include a light emitting layer. The organic light emitting stack 352 may further include a functional layer in addition to the light emitting layer. The organic light emitting stack 352 may include a hole injection layer, a hole transport layer, an electron transport layer, and an electron injection layer as functional layers in addition to the light emitting layer. The organic light emitting stack 352 may include a charge generation layer disposed between two adjacent light emitting layers in a tandem structure in which a plurality of light emitting layers overlap each other. The light emitting layer may occasionally emit light of different colors. For example, a red light emitting layer, a green light emitting layer, and a blue light emitting layer may be separately formed for each subpixel. However, a common light emitting layer may be formed for each pixel to emit white light regardless of color, and color filters for distinguishing colors may be separately provided. The classifications may be divided into an RGB type (real RGB type) and white OLED (WOLED). Each of the light emitting layers may be individually formed, but the injection layer to the transport layer may be provided as a common layer to be equally disposed for each subpixel.

The anode electrode 351 may be connected to the connecting electrode 345 exposed through the contact hole penetrating the second planarization layer 312. The anode electrode 351 may be formed in a multilayer structure including a transparent conductive film and an opaque conductive film having high reflection efficiency. The transparent conductive film may be formed of a material having a relatively large work function value, such as indium-tin-oxide (ITO) or indium-zinc-oxide (IZO), and the opaque conductive film may be formed of a single layer or multilayer structure including Al, Ag, Cu, Pb, Mo, Ti, or an alloy thereof. For example, the anode electrode 351 may be formed in a structure in which a transparent conductive film, an opaque conductive film, and a transparent conductive film are sequentially stacked, or may be formed in a structure in which a transparent conductive film and an opaque conductive film are sequentially stacked. The anode electrode 351 may be disposed on the second planarization layer 312 to overlap not only the light emitting area provided by the bank 354 but also the pixel circuit area in which the first and second transistors 320 and 330 and the storage capacitor 340 are disposed, thereby increasing the light emitting area.

The organic light emitting stack 352 may be formed by stacking a hole transport layer, an organic light emitting layer, and an electron transport layer, in the order or in the reverse order, on the anode electrode 351. Further, the organic light emitting stack 352 may further include a charge generation layer and may include first and second light emitting stacks facing each other with a charge generation layer interposed therebetween.

The bank 354 may be formed to expose the anode electrode 351. The bank 354 may be formed of an organic material such as photoacrylic, and may be a translucent material, but is not limited thereto, and may be formed of an opaque material to prevent light interference between subpixels.

The cathode electrode 353 may be formed on an upper surface of the organic light emitting stack 352 to face the anode electrode 351 with the organic light emitting stack 352 interposed therebetween. When the cathode electrode 353 is applied to the front emission organic light emitting display device, the cathode electrode 353 may be formed of a transparent conductive film by thinly forming indium-tin-oxide (ITO), indium-zinc-oxide (IZO), or magnesium-silver (Mg-Ag).

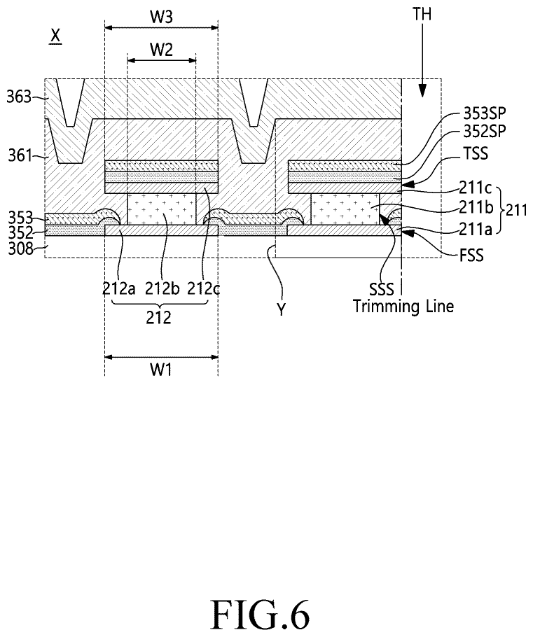

The cathode electrode 353 shown in FIG. 4 may also be referred to as a first portion 353FP of the cathode electrode 353. A second portion 353SP of the cathode electrode 353 spaced apart from the first portion 353FP of the cathode electrode 353 will be explained in detail in conjunction with FIG. 6. Similarly, the organic light emitting stack 352 shown in FIG. 4 may also be referred to as a first portion 352FP of the organic light emitting stack 352. A second portion 352SP of the organic light emitting stack 352 spaced apart from the first portion 352FP of the organic light emitting stack 352 will be explained in detail in conjunction with FIG. 6.

An encapsulation layer 360 for protecting the light emitting element 350 may be formed on the cathode electrode 353. Due to the organic material characteristics of the organic light emitting stack 352, the light emitting element 350 may react with external moisture or oxygen to cause dark spots or pixel shrinkage. To prevent this, the encapsulation layer 360 may be disposed on the cathode electrode 353.

The encapsulation layer 360 may have a single layer structure or a multilayer structure. For example, as illustrated in FIG. 4, the encapsulation layer 360 may include a first encapsulation layer 361, a second encapsulation layer 362, and a third encapsulation layer 363.

The encapsulation layer 360 may include an inorganic film including an inorganic insulating material. The encapsulation layer 360 may include an organic film including an organic material. The encapsulation layer 360 may include an inorganic film and an organic film.

For example, the first encapsulation layer 361 and the third encapsulation layer 363 may be inorganic films, and the second encapsulation layer 362 may be organic films. Among the first encapsulation layer 361, the second encapsulation layer 362, and the third encapsulation layer 363, the second encapsulation layer 362 may be the thickest. Accordingly, the second encapsulation layer 362 may serve as a planarization layer. The first encapsulation layer 361 is also referred to as a first inorganic encapsulation layer, the second encapsulation layer 362 is also referred to as an organic encapsulation layer, and the third encapsulation layer 363 is also referred to as a second inorganic encapsulation layer.

The first encapsulation layer 361 may be disposed on the cathode electrode 353 and may be disposed closest to the light emitting element 350. The first encapsulation layer 361 may be formed of an inorganic insulating material capable of low temperature deposition. For example, the first encapsulation layer 361 may be silicon nitride (SiNx), silicon oxide (SiOx), silicon oxynitride (SiON), or aluminum oxide (Al₂O₃). Since the first encapsulation layer 361 is deposited in a low-temperature atmosphere, the first encapsulation layer 361 may prevent the organic light emitting stack 352 including an organic material vulnerable to a high-temperature atmosphere from being damaged during the deposition process.

The second encapsulation layer 362 may be formed with an area smaller than that of the first encapsulation layer 361. In this case, the second encapsulation layer 362 may be formed to expose two opposite ends of the first encapsulation layer 361. The second encapsulation layer 362 may serve as a buffer to relieve stress between layers due to bending of the display device 100, and may also serve to enhance planarization performance. Further, the second encapsulation layer 362 may be referred to as a foreign object compensation layer. For example, the second encapsulation layer 362 may be an acrylic resin, an epoxy resin, polyimide, polyethylene, silicon oxycarbide (SiOC), or the like, and may be formed of an organic insulating material. For example, the second encapsulation layer 362 may be formed through an inkjet method.

The third encapsulation layer 363 may be formed on the substrate 301 on which the second encapsulation layer 362 is formed to cover the upper surface and the side surface of each of the second encapsulation layer 362 and the first encapsulation layer 361. The third encapsulation layer 363 may minimize or block external moisture or oxygen from penetrating into the first encapsulation layer 361 and the second encapsulation layer 362. For example, the third encapsulation layer 363 is formed of an inorganic insulating material such as silicon nitride (SiNx), silicon oxide (SiOx), silicon oxynitride (SiON), or aluminum oxide (Al₂O₃).

Materials of the first encapsulation layer 361 and the third encapsulation layer 363 may be different from each other. The thicknesses of the first encapsulation layer 361 and the third encapsulation layer 363 may be different from each other. The thickness of the first encapsulation layer 361 may be larger than the thickness of the third encapsulation layer 363. Alternatively, the thickness of the third encapsulation layer 363 may be larger than the thickness of the first encapsulation layer 361, or the thicknesses of the first encapsulation layer 361 and the third encapsulation layer 363 may be the same.

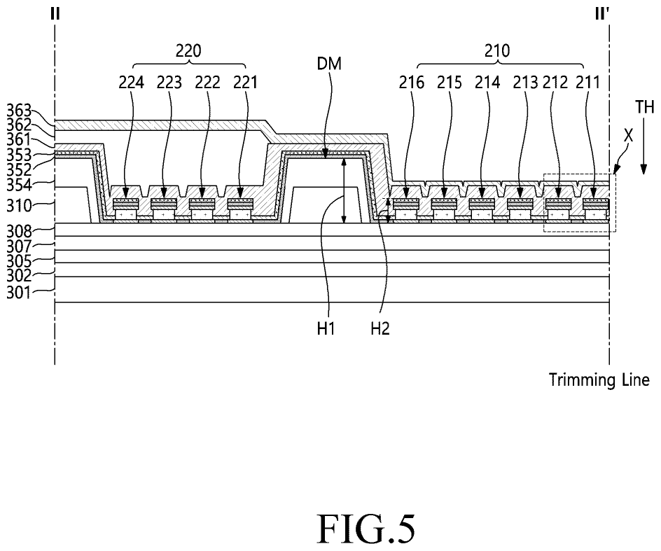

FIG. 5 is a cross-sectional view taken along line II-II′ of FIG. 3. For example, FIG. 5 is a view illustrating a cross-sectional structure of the optical area OA of FIG. 3. Those identical or similar to what has been described with reference to FIGS. 1 to 4 are omitted from the following description or are briefly described.

Referring to FIGS. 3 and 5, in the display device 100 according to embodiments of the disclosure, the optical area OA may include a through-hole TH and a HiAA bezel area HBA, and the display area AA may be positioned outside the HiAA bezel area HBA.

When looking at the cross section of the HiAA bezel area HBA, various insulation films which is disposed in the display area AA may further be disposed. For example, the buffer layer 302, the lower interlayer insulation film 305, the upper buffer layer 307, and the upper interlayer insulation film 308 may be sequentially stacked on the substrate 301.

Referring to FIGS. 3 and 5, a “dam structure” such as a dam DM (may also be referred to as a dam structure DM) may be included between the display area AA and the through-hole TH.

Such a dam structure may have a layer structure of two or more layers formed perpendicular to the substrate 301. For example, the dam structure may include a first layer formed of a planarization layer 310 and a second layer formed of a bank 354. Specifically, the dam structure may include a first layer formed of a second planarization layer 312 and a second layer formed of a bank 354. The dam structure may include a first layer formed of a second planarization layer 312, a second layer formed of a bank 354, and a third layer formed of a spacer (not shown). The dam structure may further include a first planarization layer 311 under the second planarization layer 312 or may further include another layer to have a stacked structure.

Some components constituting the light emitting element may be stacked on the dam DM. For example, the organic light emitting stack 352 and the cathode electrode 353 may be stacked in a shape of running over the dam DM.

Referring to FIG. 5, a pattern area 200 in which metal patterns 211, 212, 213, 214, 215, 216, 221, 222, 223, and 224 for preventing moisture introduced from the outside and fine cracks through a trimming line are disposed may be positioned inside and outside the dam DM. The pattern area 200 may include an outer pattern area 210 positioned between the through-hole TH and the dam DM and an inner pattern area 220 positioned between the dam DM and the display area AA.

The outer pattern area 210 may include a first metal pattern 211, a second metal pattern 212, a third metal pattern 213, a fourth metal pattern 214, a fifth metal pattern 215, and a sixth metal pattern 216. The inner pattern area 220 may include a seventh metal pattern 221, an eighth metal pattern 222, a ninth metal pattern 223, and a tenth metal pattern 224.

The first metal pattern 211 of the outer pattern area 210 is a metal pattern positioned at an edge of the outer pattern area 210 adjacent to the through-hole TH. One side portion of the first metal pattern 211 may be exposed through the through-hole TH. A side portion of the first metal pattern 211 positioned in the through-hole TH direction may be exposed through the through-hole TH.

In FIG. 5, it is illustrated that there are six metal patterns in the outer pattern area 210 and four metal patterns in the inner pattern area 220, but the disclosure is not limited thereto and various numbers of metal patterns may be configured. For example, according to the width of the metal pattern and the arrangement interval between the metal patterns, about 5 to 30 metal patterns may be configured in the outer pattern area 210, and about 2 to 15 metal patterns may be configured in the inner pattern area 220.

The first to tenth metal patterns 211, 212, 213, 214, 215, 216, 221, 222, 223, and 224 may be formed of a metallic material and may be a single layer or multiple layers, but are not limited thereto.

The first to tenth metal patterns 211, 212, 213, 214, 215, 216, 221, 222, 223, and 224 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof.

For example, each metal pattern may have a structure in which metallic materials are sequentially stacked. For example, each metal pattern may be a metal layer structure of a triple layer of Ti/Al/Ti. Further, each metal pattern may be a six-layer metal layer structure in which triple-layer metal layers are stacked.

The first to tenth metal patterns 211, 212, 213, 214, 215, 216, 221, 222, 223, and 224 may be concurrently (or in some embodiments, simultaneously) disposed of the same material as any one of the source electrodes 321 and 331, the drain electrodes 324 and 334, and the connecting electrode 345. Further, the first to tenth metal patterns 211, 212, 213, 214, 215, 216, 221, 222, 223, and 224 may be concurrently (or in some embodiments, simultaneously) disposed of the same material as the source electrodes 321 and 331 and the drain electrodes 324 and 334, and may be sequentially concurrently (or in some embodiments, simultaneously) disposed of the same material as the connecting electrode 345.

Referring to FIG. 5, the organic light emitting stack 352 may be disposed to be disconnected between metal patterns. Due to the nature of the organic material, the organic light emitting stack 352 has high reactivity and propagation properties to moisture and oxygen, so that moisture and oxygen may be transferred to the light emitting element 350 in the display area AA. To prevent this, the organic light emitting stack 352 may be partially disconnected by the metal pattern.

The metal pattern may have a concave side surface. The organic light emitting stack 352 is deposited on the front surface of the display panel 110 using straightness during deposition, but the side surface of the metal pattern has a concave shape, so that the organic light emitting stack 352 may not be formed in a concave space, and thus the organic light emitting stack 352 may be disconnected.

The organic light emitting stack 352 may be disconnected by the metal pattern to prevent penetration of oxygen and moisture through the organic light emitting stack 352.

Referring to FIG. 5, the encapsulation layer 360 may be disposed in the HiAA bezel area HBA in the same manner as the display area AA. The encapsulation layer 360 may include a first encapsulation layer 361, a second encapsulation layer 362, and a third encapsulation layer 363. The first encapsulation layer 361 and the third encapsulation layer 363 may be inorganic films, and the second encapsulation layer 362 may be organic films.

The first encapsulation layer 361 and the third encapsulation layer 363 may be disposed in the inner pattern area 220, the dam DM, and the outer pattern area 210. The first encapsulation layer 361 may be disposed on the first to tenth metal patterns 211, 212, 213, 214, 215, 216, 221, 222, 223, and 224 of the pattern area 200 and in spaces between the metal patterns. The third encapsulation layer 363 may be disposed on the first to sixth metal patterns 211, 212, 213, 214, 215, and 216 of the outer pattern area 210 and in spaces between the metal patterns.

In the outer pattern area 210, the first encapsulation layer 361 and the third encapsulation layer 363 may be disposed on the first to sixth metal patterns 211, 212, 213, 214, 215, and 216 and in spaces between the metal patterns. In the inner pattern area 220, the first encapsulation layer 361 may be disposed on the seventh to tenth metal patterns 221, 222, 223, and 224 and in spaces between the metal patterns.

As shown in FIG. 5, the dam DM has a height H1 that is greater than a height H2 of the metal pattern. In other words, the dam DM protrudes further in a direction opposite of the substrate 301 than the metal pattern.

The first encapsulation layer 361 and the third encapsulation layer 363 may be disposed to be exposed through the through-hole TH.

The second encapsulation layer 362 may be disposed in the inner pattern area 220. The second encapsulation layer 362 may be disposed only in a portion of an area near the dam DM, and may not be disposed in the outer pattern area 210.

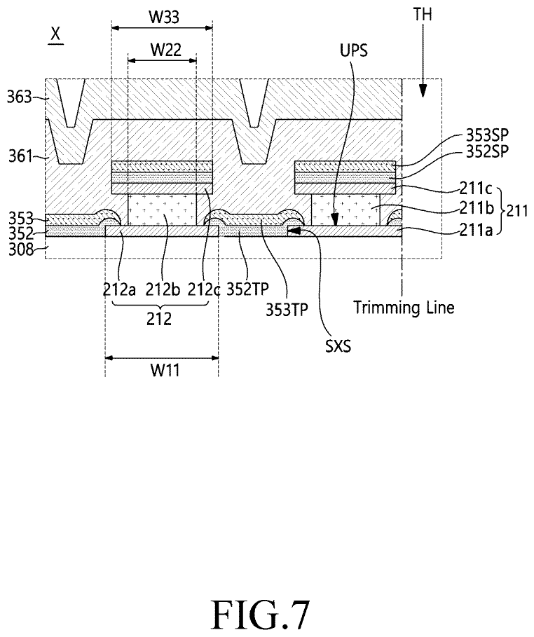

The through-hole TH extends through the substrate 301. The through-hole TH extends through various other layers disposed adjacent to the trimming line. For example, through-hole TH extends through layers 301, 302, 305, 307, 308 to expose the side portion or the side surfaces of layers 301, 302, 305, 307, 308. The through-hole TH also extends through the metal patterns to expose the side surfaces of the metal patterns. The details will be explained in connection with FIGS. 7, 8, and 9.

FIG. 6 is an example cross-sectional enlarged view illustrating area X of FIG. 5. For example, FIG. 6 is an enlarged cross-sectional view of some metal patterns 211 and 212 disposed in the outer pattern area 210. Those identical or similar to what has been described with reference to FIGS. 1 to 5 are omitted from the following description or are briefly described.

Referring to FIG. 6, the first metal pattern 211 may be positioned adjacent to the through-hole TH, and one side portion of the first metal pattern 211 may be disposed to be exposed through the through-hole TH. The first metal pattern 211 may be disposed so that a side portion positioned in a direction in which the through-hole TH is disposed is exposed through the through-hole TH.

The second metal pattern 212 may be disposed to be spaced apart from the first metal pattern 211 in the through-hole TH toward the display area AA.

Since the first metal pattern 211 and the second metal pattern 212 include the same configuration, the first metal pattern 211 is described below in detail.

The first metal pattern 211 may have a structure in which the first metal layer 211a, the second metal layer 211b, and the third metal layer 211c are sequentially stacked.

Similarly, the second metal pattern 212 may have a structure in which the first metal layer 212a, the second metal layer 212b, and the third metal layer 212c are sequentially stacked.

The side surface of the first metal pattern 211 may have a concave shape. The concave portion of the first metal pattern 211 may refer to a recess formed to be concave further inward than the side portions of the first metal layer 211a and the third metal layer 211c by removing a portion of the second metal layer 211b. In other words, the side portion of the second metal layer 211b may be disposed inside as compared with the side portion of the first metal layer 211a and the side portion of the third metal layer 211c.

Referring to FIG. 6, the width W1 of the first metal layer 211a and the width W3 of the third metal layer 211c may be larger than the width W2 of the second metal layer 211b. The width W1 of the first metal layer 211a and the width W3 of the third metal layer 211c may be the same, and the width W1 of the first metal layer 211a and the width W3 of the third metal layer 211c may be larger than the width W2 of the second metal layer 211b.

The first metal pattern 211 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but is not limited thereto.

The first metal layer 211a, the second metal layer 211b, and the third metal layer 211c may include materials having relatively different etching speeds. The second metal layer 211b may include a material having a relatively fast etching speed, and the first metal layer 211a and the third metal layer 211c may include a material having a relatively slow etching speed. The etching speed of the second metal layer 211b may be relatively faster than the etching speeds of the first metal layer 211a and the third metal layer 211c.

For example, the second metal layer 211b may include aluminum (Al) having a relatively fast etching speed, and the first metal layer 211a and the third metal layer 211c may include titanium (Ti) having a relatively slow etching speed. The first metal pattern 211 may have a triple layer structure of Ti/Al/Ti.

The first metal pattern 211 may be concurrently (or in some embodiments, simultaneously) disposed of the same material as the source electrodes 321 and 331 and the drain electrodes 324 and 334. For example, in the first metal pattern 211, the first metal layer 211a, the second metal layer 211b, and the third metal layer 211c may be sequentially stacked, in the first source electrode 321, the first electrode layer 321a, the second electrode layer 321b, and the third electrode layer 321c may be sequentially stacked, the first metal layer 211a and the first electrode layer 321a may include the same material, the second metal layer 211b and the second electrode layer 321b may include the same material, and the third metal layer 211c and the third electrode layer 321c may include the same material.

Since the other source and drain electrodes may have the same structure as the first source electrode 321, the first metal pattern 211 may include the same stacked structure and the same material as the other source and drain electrodes.

The first metal pattern 211 may be concurrently (or in some embodiments, simultaneously) disposed of the same material as the connecting electrode 345. For example, in the first metal pattern 211, the first metal layer 211a, the second metal layer 211b, and the third metal layer 211c may be sequentially stacked, in the connecting electrode 345, the first connecting electrode layer 345a, the second connecting electrode layer 345b, and the third connecting electrode layer 345c may be sequentially stacked, the first metal layer 211a and the first connecting electrode layer 345a may include the same material, the second metal layer 211b and the second connecting electrode layer 345b may include the same material, and the third metal layer 211c and the third connecting electrode layer 345c may include the same material.

Referring to FIG. 6, the first encapsulation layer 361 may be disposed to surround the first metal pattern 211. The first encapsulation layer 361 may be an inorganic film including an inorganic insulating material.

The third encapsulation layer 363 may be disposed on the first encapsulation layer 361. The third encapsulation layer 363 may be an inorganic film including an inorganic insulating material.

The first encapsulation layer 361 may be disposed on the first metal pattern 211 and the second metal pattern 212, and may be disposed in a space between the first metal pattern 211 and the second metal pattern 212.

The first encapsulation layer 361 may be disposed in a concave recess positioned in a side surface of the first metal pattern 211. The first encapsulation layer 361 may extend inward under the third metal layer 211c and may be disposed to contact the upper portion of the first metal layer 211a, the side portion of the second metal layer 211b, and the lower portion of the third metal layer 211c.

Referring to FIG. 6, the at least one organic light emitting stack 352 of the light emitting element 350 includes a first portion 352FP and a second portion 352SP spaced apart from the first portion 352FP from a plan view. The first portion 352FP of the at least one organic light emitting stack 352 overlaps with the display area AA from a plan view. Further, the second portion 352SP of the at least one organic light emitting stack 352 is on the first metal pattern 211. To be specific, the second portion 352SP of the at least one organic light emitting stack 352 is on and directly contacts the third metal layer 211c of the first metal pattern 211.

Similarly, the cathode electrode 353 of the light emitting element 350 includes a first portion 353FP and a second portion 353SP spaced apart from the first portion 353FP from a plan view. The first portion 353FP of the cathode electrode 353 overlaps with the display area AA from a plan view. Further, the second portion 353SP of the cathode electrode 353 is on the first metal pattern 211. To be specific, the second portion 353SP of the cathode electrode 353 is on and directly contacts the second portion 352SP of the at least one organic light emitting stack 352.

The first metal layer 211a and the third metal layer 211c may be disposed to be exposed through the through-hole TH. Specifically, one side portion of the first metal layer 211a and one side portion of the third metal layer 211c may be disposed to be exposed through the through-hole TH. In some embodiments, the term ‘side portion’ or ‘side surface’ may be used interchangeably.

As shown in FIG. 6, the first metal layer 211a includes a first side surface FSS facing the through-hole TH. The second metal layer 211b includes a second side surface SSS facing the through-hole TH. Here, the second side surface SSS of the second metal layer 211b is spaced apart from the through-hole TH. On the other hand, the first side surface FSS of the first metal layer 211a is exposed at the through-hole TH. That is, the first side surface FSS of the first metal layer 211a abuts with the through-hole TH. Similarly, the third metal layer 211c includes a third side surface TSS facing the through-hole TH. Here, the third side surface TSS of the third metal layer 211c is exposed at the through-hole TH. That is, the third side surface TSS of the third metal layer 211c abuts with the through-hole TH. In addition, the third side surface TSS of the third metal layer 211c is coplanar with (or in flush with) the first side surface FSS of the first metal layer 211a.

In some embodiments, depending on where the trimming line is formed, the first side surface FSS of the first metal layer 211a and the second side surface SSS of the second metal layer 211b may be exposed at the through-hole TH. In these embodiments, the first side surface FSS of the first metal layer 211a and the second side surface SSS of the second metal layer 211b may be coplanar with each other.

Since the first encapsulation layer 361, which is an inorganic film, may be disposed to contact the upper portion and the inside under the third metal layer 211c, a fixing stress may be applied to the first encapsulation layer 361 and the third metal layer 211c, thereby enhancing the bonding force between the first metal pattern 211 and the first encapsulation layer 361.

One side portion of the first metal layer 211a and one side portion of the third metal layer 211c of the first metal pattern 211 may be disposed to be exposed through the through-hole TH to block the moisture permeation path by the organic light emitting stack.

The bonding force between the first metal pattern 211 and the first encapsulation layer 261 which is an inorganic film may be enhanced, and the moisture permeation path by the organic light emitting stack 352 may be blocked to prevent or reduce side moisture permeation by delamination.

FIG. 7 is another example cross-sectional enlarged view illustrating area X of FIG. 5. For example, FIG. 7 is another enlarged view illustrating a cross-sectional structure of some metal patterns 211 and 212 disposed in the outer pattern area 210. What is identical or similar to those described with reference to FIGS. 1 to 6 is omitted from the following description or briefly described below.

Referring to FIG. 7, the first metal pattern 211 may be positioned adjacent to the through-hole TH, and one side portion of the first metal pattern 211 may be disposed to be exposed through the through-hole TH. The first metal pattern 211 may be disposed so that a side portion positioned in a direction in which the through-hole TH is disposed is exposed through the through-hole TH.

The first metal pattern 211 may have a structure in which the first metal layer 211a, the second metal layer 211b, and the third metal layer 211c are sequentially stacked.

The side surface of the first metal pattern 211 may have a concave shape. The concave portion of the first metal pattern 211 may refer to a recess formed to be concave further inward than the side portions of the first metal layer 211a and the third metal layer 211c by removing a portion of the second metal layer 211b. In other words, the side portion of the second metal layer 211b may be disposed inside as compared with the side portion of the first metal layer 211a and the side portion of the third metal layer 211c.

Referring to FIG. 7, the width W11 of the first metal layer 211a and the width W33 of the third metal layer 211c may be larger than the width W22 of the second metal layer 211b. The width W11 of the first metal layer 211a may be larger than the width W33 of the third metal layer 211c.

Referring to FIG. 7, the first encapsulation layer 361 may be disposed to surround the first metal pattern 211. The first encapsulation layer 361 may be an inorganic film including an inorganic insulating material.

The third encapsulation layer 363 may be disposed on the first encapsulation layer 361. The third encapsulation layer 363 may be an inorganic film including an inorganic insulating material.

The first encapsulation layer 361 may be disposed on the first metal pattern 211 and the second metal pattern 212, and may be disposed in a space between the first metal pattern 211 and the second metal pattern 212.

The first encapsulation layer 361 may be disposed in a concave recess positioned in a side surface of the first metal pattern 211. The first encapsulation layer 361 may extend inward under the third metal layer 211c and may be disposed to contact an upper portion of the first metal layer 211a, a side portion of the second metal layer 211b, and a side portion and a lower portion of the third metal layer 211c.

As shown in FIG. 7, the at least one organic light emitting stack 352 of the light emitting element 350 further includes a third portion 352TP. The first portion 352FP, the second portion 352SP, and the third portion 352TP are spaced apart from each other. In some embodiments, the second portion 352SP of the at least one organic light emitting stack 352 overlaps with the third portion 352TP of the at least one organic light emitting stack 352 from a plan view.

The third portion 352TP of the at least one organic light emitting stack 352 is in contact with a third side surface SXS of the first metal layer 211a and an upper surface UPS of the first metal layer 211a.

Similarly, the cathode electrode 353 includes a first portion 353FP and a second portion 353SP spaced apart from the first portion 353FP. Here, the first portion 353FP of the cathode electrode 353 overlaps with the display area AA from a plan view. The second portion 353SP of the cathode electrode 353 is on the second portion 352SP of the at least one organic light emitting stack 352. The second portion 352SP of the at least one organic light emitting stack 352 includes a first side surface, and a second side surface opposite the first side surface, and an upper surface between the first side surface and the second side surface. In some embodiments, the second portion 353SP of the cathode electrode 353 directly contacts the first side surface and the upper surface of the second portion 352SP of the at least one organic light emitting stack 352. In addition, in some embodiments, the second side surface of the second portion 352SP of the at least one organic light emitting stack 352 is exposed at the through-hole TH.

The first metal layer 211a may be disposed to be exposed through the through-hole TH. Specifically, one side portion of the first metal layer 211a may be disposed to be exposed through the through-hole TH.

Since the first encapsulation layer 361, which is an inorganic film, may be disposed to contact the upper portion, side portions, and the inside under the third metal layer 211c, a fixing stress may be applied to the first encapsulation layer 361 and the third metal layer 211c, thereby enhancing the bonding force between the first metal pattern 211 and the first encapsulation layer 361.

One side portion of the first metal layer 211a of the first metal pattern 211 may be disposed to be exposed through the through-hole TH to block the moisture permeation path by the organic light emitting stack.

The bonding force between the first metal pattern 211 and the first encapsulation layer 261 which is an inorganic film may be enhanced, and the moisture permeation path by the organic light emitting stack 352 may be blocked to prevent or reduce side moisture permeation by delamination.

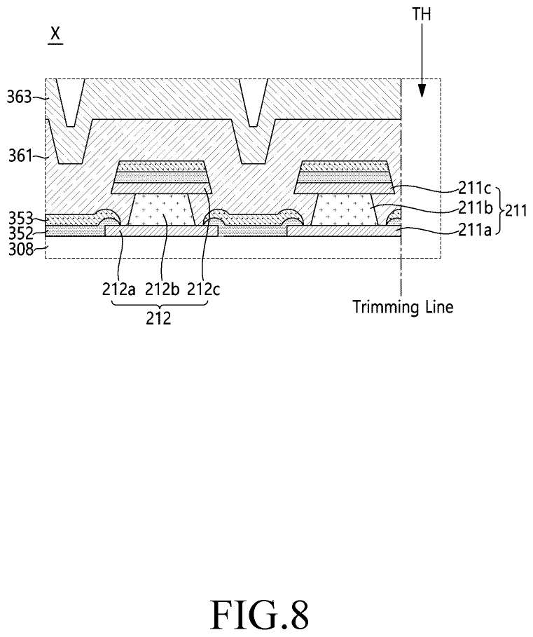

FIG. 8 is another example cross-sectional enlarged view illustrating area X of FIG. 5. For example, FIG. 8 is another enlarged view illustrating a cross-sectional structure of some metal patterns 211 and 212 disposed in the outer pattern area 210. What is identical or similar to those described with reference to FIGS. 1 to 7 is omitted from the following description or briefly described below.

Referring to FIG. 8, the first metal pattern 211 may be positioned adjacent to the through-hole TH, and one side portion of the first metal pattern 211 may be disposed to be exposed through the through-hole TH. The first metal pattern 211 may be disposed so that a side portion positioned in a direction in which the through-hole TH is disposed is exposed through the through-hole TH.

The first metal pattern 211 may have a structure in which the first metal layer 211a, the second metal layer 211b, and the third metal layer 211c are sequentially stacked.

The side surface of the first metal pattern 211 may have a concave shape. The concave portion of the first metal pattern 211 may refer to a recess formed to be concave further inward than the side portions of the first metal layer 211a and the third metal layer 211c by removing a portion of the second metal layer 211b. In other words, the side portion of the second metal layer 211b may be disposed inside as compared with the side portion of the first metal layer 211a and the side portion of the third metal layer 211c.

Referring to FIG. 8, each of the first metal layer 211a, the second metal layer 211b, and the third metal layer 211c may have a forward tapered shape.

Referring to FIG. 8, the width of the first metal layer 211a and the width of the third metal layer 211c may be larger than the width of the second metal layer 211b. The width of the first metal layer 211a may be larger than the width of the third metal layer 211c. Although not shown, the width of the first metal layer 211a and the width of the third metal layer 211c may be the same, and the width of the first metal layer 211a and the width of the third metal layer 211c may be larger than the width of the second metal layer 211b.

Referring to FIG. 8, the first encapsulation layer 361 may be disposed to surround the first metal pattern 211. The first encapsulation layer 361 may be an inorganic film including an inorganic insulating material.

The third encapsulation layer 363 may be disposed on the first encapsulation layer 361. The third encapsulation layer 363 may be an inorganic film including an inorganic insulating material.

The first encapsulation layer 361 may be disposed on the first metal pattern 211 and the second metal pattern 212, and may be disposed in a space between the first metal pattern 211 and the second metal pattern 212.

The first encapsulation layer 361 may be disposed in a concave recess positioned in a side surface of the first metal pattern 211. The first encapsulation layer 361 may extend inward under the third metal layer 211c and may be disposed to contact an upper portion of the first metal layer 211a, a side portion of the second metal layer 211b, and a side portion and a lower portion of the third metal layer 211c.

The first metal layer 211a may be disposed to be exposed through the through-hole TH. Specifically, one side portion of the first metal layer 211a may be disposed to be exposed through the through-hole TH.

Since the first encapsulation layer 361, which is an inorganic film, may be disposed to contact the upper portion, side portions, and the inside under the third metal layer 211c, a fixing stress may be applied to the first encapsulation layer 361 and the third metal layer 211c, thereby enhancing the bonding force between the first metal pattern 211 and the first encapsulation layer 361. Since the first metal layer 211a, the second metal layer 211b, and the third metal layer 211c each have a forward tapered shape, the bonding force between the first metal pattern 211 and the first encapsulation layer 361 may be further enhanced.

One side portion of the first metal layer 211a of the first metal pattern 211 may be disposed to be exposed through the through-hole TH to block the moisture permeation path by the organic light emitting stack.

The bonding force between the first metal pattern 211 and the first encapsulation layer 261 which is an inorganic film may be enhanced, and the moisture permeation path by the organic light emitting stack 352 may be blocked to prevent or reduce side moisture permeation by delamination.

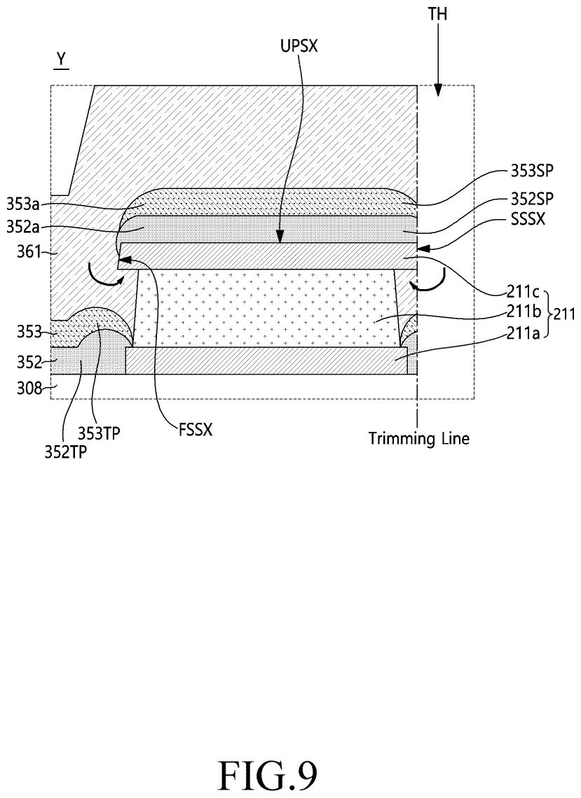

FIG. 9 is an example cross-sectional enlarged view illustrating area Y of FIG. 6. What is identical or similar to those described with reference to FIGS. 1 to 8 is omitted from the following description or briefly described below.

Referring to FIG. 9, the first metal pattern 211 may have a structure in which the first metal layer 211a, the second metal layer 211b, and the third metal layer 211c are stacked and disposed. The width of the third metal layer 211c may be larger than the width of the second metal layer 211b. An organic light emitting stack 352 and a second electrode 353 may be stacked and disposed on the third metal layer 211c. Specifically, the organic light emitting stack 352 and the second electrode 353 may be disposed to extend from a side portion of the third metal layer 211c. The organic light emitting stack 352 and the second electrode 353 may be disposed to cover a side portion of the third metal layer 211c. Specifically, the third metal layer 211c may include a first side surface FSSX, and a second side surface SSSX opposite the first side surface FSSX, and an upper surface UPSX between the first side surface FSSX and the second side surface SSSX. The second portion 352SP of the organic light emitting stack 352 may directly contact the first side surface FSSX and the upper surface UPSX of the third metal layer 211c. In addition, the second side surface SSSX of the third metal layer 211c may be exposed at the through-hole TH.

The first encapsulation layer 361, which is an inorganic film, may be disposed to contact the upper portion, side portions, and the inside under the third metal layer 211c. The first encapsulation layer 361 may be in direct contact with the third metal layer 211c at a portion of the side portion and under the third metal layer 211c. Since the first encapsulation layer 361 is disposed to be in direct contact with the third metal layer 211c, a fixing stress between the first encapsulation layer 361 and the third metal layer 211c may act, resultantly enhancing the bonding force between the first metal pattern 211 and the first encapsulation layer 361.

Even if the through-hole is formed by laser cutting, the fixing stress between the third metal layer 211c of the first metal pattern 211 exposed through the through-hole and the first encapsulation layer 361 which is an inorganic film may be maintained, thereby enhancing the bonding force between the first metal pattern 211 and the first encapsulation layer 361. Further, side portions of some metal layers of the first metal pattern 211 are exposed through the through-hole to block the moisture permeation path by the organic light emitting stack 352.

In other words, the bonding force between the first metal pattern 211 and the first encapsulation layer 361 which is an inorganic film may be enhanced, and the moisture permeation path by the organic light emitting stack 352 may be blocked, preventing or reducing side moisture permeation by delamination.

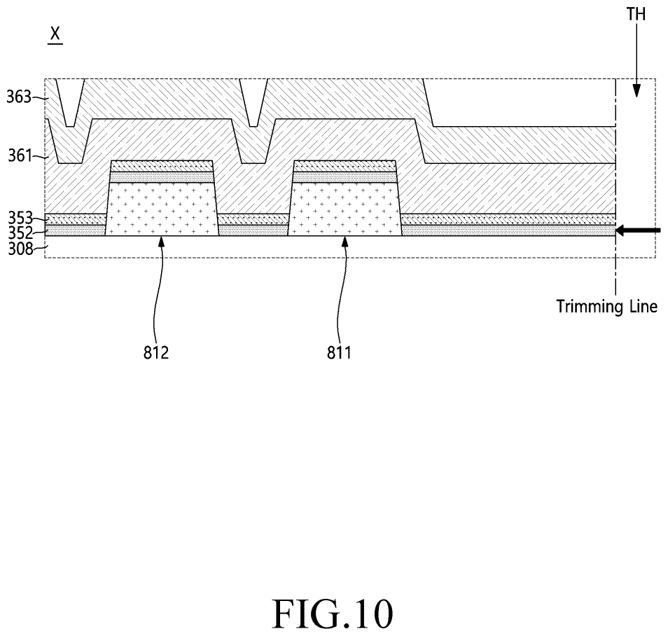

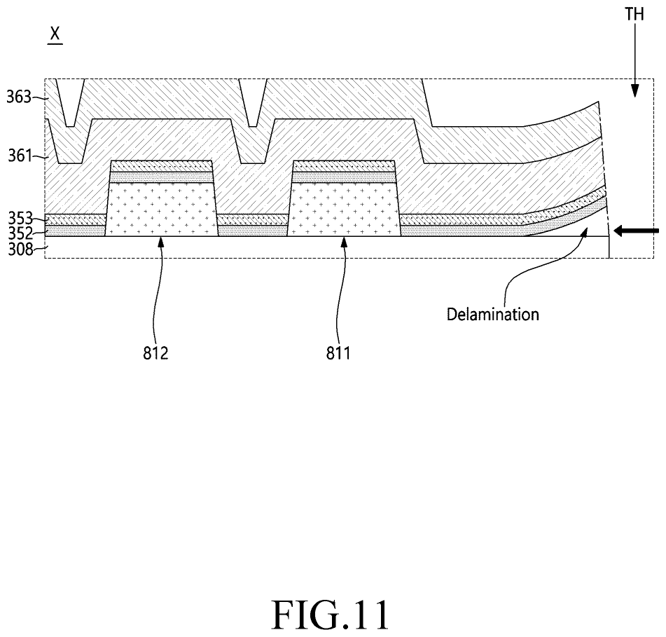

FIG. 10 is a view illustrating a moisture permeation path in a hole area boundary of a display panel, and FIG. 11 is a view illustrating delamination caused due to moisture permeation. Those identical or similar to what has been described with reference to FIGS. 1 to 9 are omitted from the following description or are briefly described.

Referring to FIG. 10, the first metal pattern 811 and the second metal pattern 812 are spaced apart from the through-hole TH, and the organic light emitting stack 352 is positioned between the first metal pattern 811 and the through-hole TH.

The organic light emitting stack 352 may be a moisture permeation path from the cut surface of the through-hole TH to the side surface, and delamination may occur due to moisture permeation.

Referring to FIGS. 10 and 11, moisture permeates into the organic light emitting stack 352 disposed between the upper interlayer insulation film 308 and the first encapsulation layer 361. When moisture permeates into the organic light emitting stack 352, the bonding force with the adjacent upper interlayer insulation film 308 decreases, and due to the reduced bonding force, delamination occurs in which the organic film including the organic light emitting stack 352 is separated from the upper interlayer insulation film 308 which is an inorganic film. Since there is no structure capable of blocking moisture introduced from the side and the cut surface of the through-hole TH to the side surface of the organic light emitting stack 352, the organic light emitting stack 352 becomes a moisture permeation path, causing delamination due to the moisture penetration.

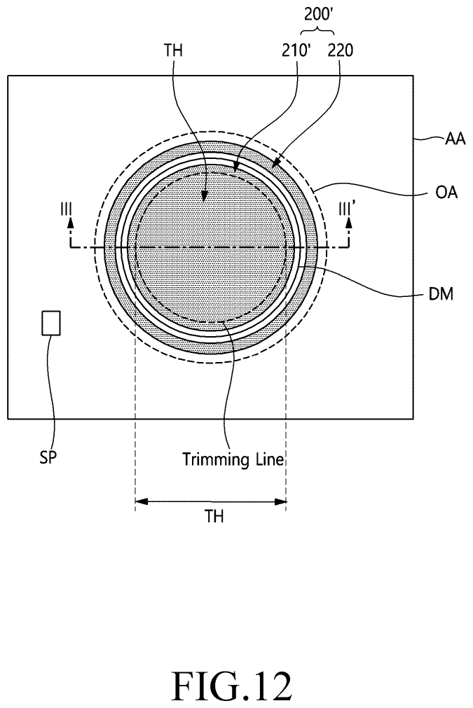

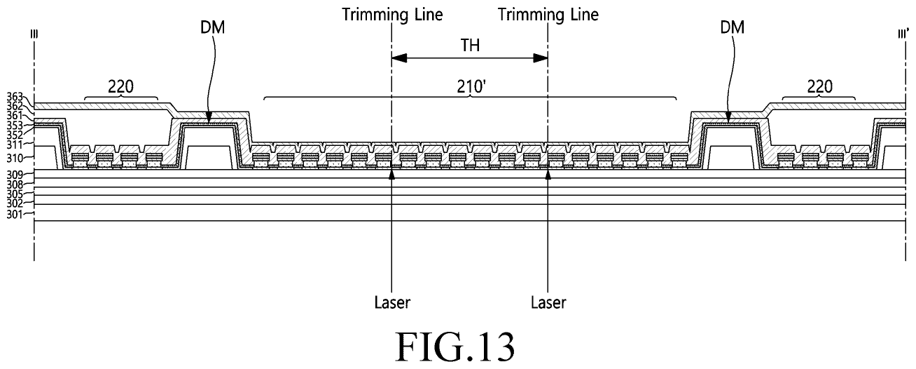

FIGS. 12 and 13 are views illustrating a process for forming an optical area of a display panel according to embodiments of the disclosure. What is identical or similar to those described with reference to FIGS. 1 to 11 is omitted from the following description or briefly described below.

Referring to FIGS. 12 and 13, a metal pattern having a diameter smaller than the diameter of the dam DM may be disposed in a concentric circle in the outer pattern area 210′. In other words, the metal pattern may have a diameter from a size smaller than the diameter of the through-hole TH to a size larger than the diameter of the through-hole TH.

The metal pattern may have a structure in which the first metal layer, the second metal layer, and the third metal layer are sequentially stacked. The metal pattern may be concurrently (or in some embodiments, simultaneously) disposed of the same material as the source electrode and the drain electrode. Further, the metal pattern may be concurrently (or in some embodiments, simultaneously) disposed of the same material as the connecting electrode.

After the first metal layer, the second metal layer, and the third metal layer are sequentially disposed and patterned, the metal pattern may be etched by an etching process. In the etching process, the etching speed of the second metal layer may be relatively faster than the etching speeds of the first metal layer and the third metal layer.

After the etching process is completed, the organic light emitting stack and the second electrode may be sequentially stacked and disposed.

An encapsulation layer may be disposed on the front surface of the substrate.

A through-hole TH may be formed by cutting with a laser along the cutting line. In this case, one side portion of the metal pattern may be cut with a laser so as to be exposed through the through-hole TH.

Since the metal patterns are continuously arranged, the limit to the number of metal patterns due to the cutting margin of the through-hole TH may be freed, thereby enabling process optimization.

Embodiments of the disclosure described above are briefly described below.

According to embodiments of the disclosure, there may be provided a display device comprising a substrate including a display area, a through-hole, and a non-display area between the display area and the through-hole, a light emitting element disposed in the display area, a pattern area disposed in the non-display area and including at least one metal pattern, and an encapsulation layer positioned on the light emitting element and including an inorganic film, wherein the inorganic film is disposed in the pattern area, and wherein a side portion of a metal pattern adjacent to the through-hole among the at least one metal pattern is exposed through the through-hole.

In the display device according to embodiments of the disclosure, the metal pattern may include a first metal layer, a second metal layer, and a third metal layer sequentially stacked, and a side portion of the second metal layer may be formed to be further concave toward inside of the metal pattern as compared with a side portion of the first metal layer and a side portion of the third metal layer.

In the display device according to embodiments of the disclosure, at least one of a side portion of the first metal layer or a side portion of the third metal layer of the metal pattern adjacent to the through-hole may be exposed through the through-hole.

In the display device according to embodiments of the disclosure, a width of the first metal layer may be larger than a width of the third metal layer.

In the display device according to embodiments of the disclosure, each of the first metal layer, the second metal layer, and the third metal layer has a forward tapered shape.

In the display device according to embodiments of the disclosure, the inorganic film may be disposed to extend inward under the third metal layer.

In the display device according to embodiments of the disclosure, the metal pattern may have a closed circuit shape to surround the through-hole.

The display device according to embodiments of the disclosure may further comprise a dam disposed between the display area and the through-hole. The pattern area may include an inner pattern area disposed between the display area and the dam and an outer pattern area disposed between the dam and the through-hole.

In the display device according to embodiments of the disclosure, the light emitting element may include a first electrode, a second electrode, and an organic light emitting stack positioned between the first electrode and the second electrode. The organic light emitting stack and the second electrode extend to the non-display area and may be disconnected by the metal pattern.

The display device according to embodiments of the disclosure may further comprise a transistor positioned on the substrate and including a semiconductor layer, a gate electrode overlapping the semiconductor layer, and a source electrode and a drain electrode electrically connected to the semiconductor layer.

In the display device according to embodiments of the disclosure, the metal pattern may be concurrently (or in some embodiments, simultaneously) disposed of the same material as the source electrode and the drain electrode.

In the display device according to embodiments of the disclosure, the metal pattern may include a first metal layer, a second metal layer, and a third metal layer sequentially stacked. The source electrode and the drain electrode may include a first electrode layer, a second electrode layer, and a third electrode layer sequentially stacked. The first metal layer and the first electrode layer may include the same material, the second metal layer and the second electrode layer may include the same material, and the third metal layer and the third electrode layer may include the same material.

The display device according to embodiments of the disclosure may further comprise a planarization layer disposed on the transistor and a connection electrode positioned on the planarization layer and electrically connecting the light emitting element and the transistor.

In the display device according to embodiments of the disclosure, the metal pattern may be concurrently (or in some embodiments, simultaneously) disposed of the same material as the connection electrode.

In the display device according to embodiments of the disclosure, the metal pattern may include a first metal layer, a second metal layer, and a third metal layer sequentially stacked. The connection electrode may include a first connection electrode layer, a second connection electrode layer, and a third connection electrode layer. The first metal layer and the first connection electrode layer may include the same material. The second metal layer and the second connection electrode layer may include the same material. The third metal layer and the third connection electrode layer may include the same material.

According to embodiments of the disclosure, there may be provided a display device comprising a substrate, a through-hole formed by removing at least a portion of the substrate, a display area positioned around the through-hole, wherein a subpixel including a light emitting element and a transistor for driving the light emitting element is disposed in the display area, a pattern area positioned between the display area and the through-hole and including a metal pattern having a side portion exposed through the through-hole, and an inorganic film disposed on the light emitting element and the pattern area.

In the display device according to embodiments of the disclosure, the metal pattern may include a first metal layer, a second metal layer, and a third metal layer sequentially stacked. A side portion of the second metal layer may be formed to be further concave toward inside of the metal pattern as compared with a side portion of the first metal layer and a side portion of the third metal layer. The inorganic film may be disposed to extend inward above and under the third metal layer.

In the display device according to embodiments of the disclosure, the transistor may include a semiconductor layer positioned on the substrate, a gate insulation film positioned on the semiconductor layer, a gate electrode positioned on the gate insulation film and overlapping the semiconductor layer, an interlayer insulation film positioned on the gate electrode, and a source electrode and a drain electrode positioned on the interlayer insulation film and electrically connected to the semiconductor layer.

The display device according to embodiments of the disclosure may further comprise a planarization layer disposed on the transistor and a connection electrode positioned on the planarization layer and electrically connecting the light emitting element and the transistor.

In the display device according to embodiments of the disclosure, the metal pattern may be concurrently (or in some embodiments, simultaneously) disposed of the same material as any one of the source electrode, the drain electrode, and the connection electrode.

A display device according to some embodiments include:
a substrate;
a through-hole formed by removing at least a portion of the substrate;
a display area positioned around the through-hole, wherein a subpixel including a light emitting element and a transistor for driving the light emitting element is disposed in the display area;
a pattern area positioned between the display area and the through-hole and including a metal pattern having a side portion exposed through the through-hole; and
an inorganic film disposed on the light emitting element and the pattern area.

In some embodiments, the metal pattern includes a first metal layer, a second metal layer, and a third metal layer sequentially stacked.

In some embodiments, a side portion of the second metal layer is formed to be further concave toward inside of the metal pattern as compared with a side portion of the first metal layer and a side portion of the third metal layer.

In some embodiments, the inorganic film is disposed to extend inward above and under the third metal layer.

In some embodiments, the transistor includes:
a semiconductor layer positioned on the substrate;
a gate insulation film positioned on the semiconductor layer;
a gate electrode positioned on the gate insulation film and overlapping the semiconductor layer;
an interlayer insulation film positioned on the gate electrode; and
a source electrode and a drain electrode positioned on the interlayer insulation film and electrically connected to the semiconductor layer.

In some embodiments, the display device further includes a planarization layer disposed on the transistor; and a connection electrode positioned on the planarization layer and electrically connecting the light emitting element and the transistor.

In some embodiments, the metal pattern is simultaneously disposed of the same material as any one of the source electrode, the drain electrode, and the connection electrode.

A display device according to embodiments of the disclosure may have an enhanced coupling force as a fixing stress acts between an inorganic film and an upper metal layer of a metal pattern.

In a display device according to embodiments of the disclosure, it is possible to block moisture permeation path due to an organic light emission stack by disposing a side portion of some metal layer of a metal pattern to be exposed through a through hole.

In a display device according to embodiments of the disclosure, it is possible to prevent or reduce side moisture permeation due to delamination by blocking the moisture permeation path due to an inorganic light emission stack while enhancing the coupling force between the metal pattern and the inorganic film.

In a display device according to embodiments of the disclosure, it is possible to achieve process optimization without a limit to the number of metal patterns due to a cut margin of a through hole as metal patterns are consecutively disposed.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area, a through-hole, and a non-display area between the display area and the through-hole;
a light emitting element disposed in the display area;
a pattern area disposed in the non-display area, the pattern area including at least one metal pattern, the at least one metal pattern including a metal pattern adjacent to the through-hole; and
an encapsulation layer positioned on the light emitting element, the encapsulation layer including an inorganic film,
wherein the inorganic film is disposed in the pattern area,
wherein the metal pattern has a side portion, and
wherein the side portion of the metal pattern is exposed through the through-hole.

2. The display device of claim 1, wherein the metal pattern includes a first metal layer, a second metal layer, and a third metal layer sequentially stacked,
wherein a side portion of the second metal layer is formed to be further concave toward inside of the metal pattern as compared with a side portion of the first metal layer and a side portion of the third metal layer, and
wherein at least one of a side portion of the first metal layer or a side portion of the third metal layer of the metal pattern adjacent to the through-hole is exposed through the through-hole.

3. The display device of claim 2, wherein each of the first metal layer, the second metal layer, and the third metal layer has a forward tapered shape.

4. The display device of claim 2, wherein the inorganic film is disposed to extend inward under the third metal layer.

5. The display device of claim 1, further comprising a dam disposed between the display area and the through-hole,
wherein the pattern area includes an inner pattern area disposed between the display area and the dam and an outer pattern area disposed between the dam and the through-hole.

6. The display device of claim 1, wherein the light emitting element includes a first electrode, a second electrode, and an organic light emitting stack positioned between the first electrode and the second electrode, and
wherein the organic light emitting stack and the second electrode extend to the non-display area and are disconnected by the metal pattern.

7. The display device of claim 1, further comprising a transistor positioned on the substrate, the transistor including a semiconductor layer, a gate electrode overlapping the semiconductor layer, and a source electrode and a drain electrode electrically connected to the semiconductor layer, wherein the metal pattern is concurrently disposed of a same material as the source electrode and the drain electrode.

8. The display device of claim 7, wherein the metal pattern includes a first metal layer, a second metal layer, and a third metal layer sequentially stacked,
wherein the source electrode and the drain electrode include a first electrode layer, a second electrode layer, and a third electrode layer sequentially stacked,
wherein the first metal layer and the first electrode layer include a same material,
wherein the second metal layer and the second electrode layer include a same material, and
wherein the third metal layer and the third electrode layer include a same material.

9. The display device of claim 7, further comprising:
a planarization layer disposed on the transistor; and
a connection electrode positioned on the planarization layer and electrically connecting the light emitting element and the transistor.

10. The display device of claim 9, wherein the metal pattern is concurrently disposed of a same material as any one of the source electrode, the drain electrode, and the connection electrode.

11. The display device of claim 9, wherein the metal pattern includes a first metal layer, a second metal layer, and a third metal layer sequentially stacked,
wherein the connection electrode includes a first connection electrode layer, a second connection electrode layer, and a third connection electrode layer,
wherein the first metal layer and the first connection electrode layer include a same material,
wherein the second metal layer and the second connection electrode layer include a same material, and
wherein the third metal layer and the third connection electrode layer include a same material.

12. The display device of claim 2, further comprising an organic light emitting element pattern disposed on the third metal layer,
wherein the organic light emitting element pattern is disposed to extend from a side portion of the third metal layer.

13. A display device, comprising:
a substrate having thereon a display area and a non-display area adjacent to the display area,
a through-hole extending through the substrate, the through-hole between the display area and the non-display area;
a light emitting element having an anode electrode, a cathode electrode, and at least one organic light emitting stack between the anode electrode and the cathode electrode;
a metal pattern between the through-hole and the display area, the metal pattern surrounding the through-hole from a plan view;
wherein the at least one organic light emitting stack of the light emitting element includes a first portion and a second portion spaced apart from the first portion from a plan view,
wherein the first portion of the at least one organic light emitting stack overlaps with the display area from a plan view, and
wherein the second portion of the at least one organic light emitting stack is on the metal pattern.

14. The display device of claim 13, further comprising:
a dam structure between the through-hole and the display area,
wherein the dam structure surrounds the through-hole from a plan view,
wherein the dam structure is adjacent to the metal pattern,
wherein the metal pattern is a first metal pattern and the first metal pattern is between the dam structure and the through-hole from a plan view,
wherein the display device further includes a second metal pattern different from the first metal pattern, and
wherein the dam structure is between the first metal pattern and the second metal pattern from a plan view.

15. The display device of claim 13, wherein the metal pattern includes a first metal layer and a second metal layer on the first metal layer,
wherein the second portion of the at least one organic light emitting stack is on the second metal layer of the metal pattern.

16. The display device of claim 15, wherein the first metal layer includes a first side surface facing the through-hole,
wherein the second metal layer includes a second side surface facing the through-hole,
wherein either the second side surface of the second metal layer is spaced apart from the through-hole, or the first side surface of the first metal layer and the second side surface of the second metal layer is exposed at the through-hole.

17. The display device of claim 13, wherein the at least one organic light emitting stack of the light emitting element further includes a third portion,
wherein the first portion, the second portion, and the third portion are spaced apart from each other,
wherein the second portion of the at least one organic light emitting stack overlaps with the third portion of the at least one organic light emitting stack from a plan view, and
wherein the third portion of the at least one organic light emitting stack is in contact with of a third side surface of the first metal layer and an upper surface of the first metal layer.

18. The display device of claim 13, wherein the metal pattern includes a first metal layer, a second metal layer on the first metal layer, and a third metal layer on the second metal layer,
wherein the third metal layer includes a first side surface, and a second side surface opposite the first side surface, and an upper surface between the first side surface and the second side surface,
wherein the second portion of the at least one organic light emitting stack directly contacts the first side surface and the upper surface of the third metal layer of the metal pattern.

19. The display device of claim 18, wherein the cathode electrode includes a first portion and a second portion spaced apart from the first portion,
wherein the first portion of the cathode electrode overlaps with the display area from a plan view,
wherein the second portion of the cathode electrode is on the second portion of the at least one organic light emitting stack,
wherein the second portion of the at least one organic light emitting stack includes a first side surface, and a second side surface opposite the first side surface, and an upper surface between the first side surface and the second side surface,
wherein the second portion of the cathode electrode directly contacts the first side surface and the upper surface of the second portion of the at least one organic light emitting stack, and
wherein the second side surface of the second portion of the at least one organic light emitting stack is exposed at the through-hole.

20. The display device of claim 18, wherein the second side surface of the third metal layer is exposed at the through-hole.
